(19) United States
(12) Patent Application Publication
(10) Pub. No.: US 2022/0139706 A1
(43) Pub. Date: May 5, 2022

(54) METHODS AND APPARATUS FOR PROCESSING A SUBSTRATE

(71) Applicant: APPLIED MATERIALS, INC., Santa Clara, CA (US)

(72) Inventors: Yaoying ZHONG, Singapore (SG); Siew Kit HOI, Singapore (SG); Zicheng JIANG, Singapore (SG)

(21) Appl. No.: 17/086,555

(22) Filed: Nov. 2, 2020

(51) Int. Cl. H01L 21/02; C23C 16/503; C23C 16/505; C23C 16/455; C23C 16/52; H01L 21/67

(52) U.S. Cl. CPC H01L 21/02274; C23C 16/503; C23C 16/505; H01L 21/6719; C23C 16/52; H01L 21/67023; C23C 16/45536

(57) ABSTRACT

Methods and apparatus for processing a substrate are provided herein. For example, a method includes supplying a first gas at a first flow rate to a substrate support disposed within an interior volume of a deposition chamber and at a second flow rate into the interior volume of the deposition chamber; decreasing the first flow rate of the first gas to a third flow rate; supplying DC power or DC power and an AC power for inducing an AC bias therebetween; supplying a second gas into the deposition chamber in a switching mode while supplying the first gas at the second flow rate and the third flow rate and increasing at least one of the DC power or AC power to increase the AC bias; and while supplying the second gas in the switching mode, depositing material from the target onto a substrate to form a barrier layer.

### FIELD

Embodiments of the present disclosure generally relate to a methods and apparatus for processing a substrate, and more particularly, to methods and apparatus configured to improve a tantalum nitride (TaN) barrier disposed between two layers of material.

### BACKGROUND

Conventional methods and apparatus that are configured to provide TaN barriers are known. For example, conventional methods and apparatus sometimes use specialized deposition chambers (e.g., ionize-physical deposition chambers (PVD)), provide O₂ air breaks, and/or provide relatively thick TaN barriers. Such methods and apparatus, however, are very costly, have very low throughput, and/or can increase contact resistance (RC).

### SUMMARY

Methods and apparatus for processing a substrate are provided herein. In some embodiments, the method includes supplying a first gas at a first flow rate to a substrate support disposed within an interior volume of a deposition chamber and at a second flow rate into the interior volume of the deposition chamber; decreasing the first flow rate of the first gas to a third flow rate; supplying at least one of a DC power or DC power and an AC power to at least one of the substrate support or a target disposed in the deposition chamber for inducing an AC bias therebetween; supplying a second gas into the deposition chamber in a switching mode that alters a flow rate of the second gas while supplying the first gas at the second flow rate and the third flow rate and increasing at least one of the DC power or AC power to increase the AC bias; and while supplying the second gas in the switching mode, depositing material from the target onto a substrate disposed on the substrate support to form a barrier layer on the substrate.

In at least some embodiments, a non-transitory computer readable storage medium having instructions stored thereon that, when executed by a processor, cause a method for processing a substrate to be performed. The method includes supplying a first gas at a first flow rate to a substrate support disposed within an interior volume of a deposition chamber and at a second flow rate into the interior volume of the deposition chamber; decreasing the first flow rate of the first gas to a third flow rate; supplying at least one of a DC power or DC power and an AC power to at least one of the substrate support or a target disposed in the deposition chamber for inducing an AC bias therebetween; supplying a second gas into the deposition chamber in a switching mode that alters a flow rate of the second gas while supplying the first gas at the second flow rate and the third flow rate and increasing at least one of the DC power or AC power to increase the AC bias; and while supplying the second gas in the switching mode, depositing material from the target onto a substrate disposed on the substrate support to form a barrier layer on the substrate.

In at least some embodiments, a deposition chamber for processing a substrate includes a gas source configured to provide at least one gas into the deposition chamber; a DC power source and an RF power source configured to induce an AC bias between a substrate support and a target each disposed within an interior volume of the deposition chamber; and a controller configured to: supply a first gas at a first flow rate to the substrate support disposed within the interior volume of the deposition chamber and at a second flow rate into the interior volume of the deposition chamber; decrease the first flow rate of the first gas to a third flow rate; supply at least one of a DC power or DC power and an AC power to at least one of the substrate support or the target disposed in the deposition chamber for inducing the AC bias therebetween; supply a second gas into the deposition chamber in a switching mode that alters a flow rate of the second gas while supplying the first gas at the second flow rate and the third flow rate and increasing at least one of the DC power or AC power to increase the AC bias; and while supplying the second gas in the switching mode, depositing material from the target onto a substrate disposed on the substrate support to form a barrier layer of the substrate.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic, cross-sectional view of a processing chamber in accordance with at least some embodiments of the present disclosure.

FIG. 2 is a flowchart of a method of processing a substrate in accordance with at least some embodiments of the present disclosure.

FIG. 3 is a partial cross-section of a cover ring in accordance with at least some embodiments of the present disclosure.

FIG. 4 is a schematic cross-sectional side view of a substrate formed using the method of FIG. 2 in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of a methods and apparatus for processing a substrate are provided herein. For example, methods and apparatus described herein are configured to deposit an improved tantalum nitride (TaN) barrier between two layers of material disposed on a substrate. Unlike conventional methods and apparatus configured to deposit TaN barriers, the methods and apparatus described herein advantageously are relatively inexpensive, have very high throughput and/or can decrease RC.

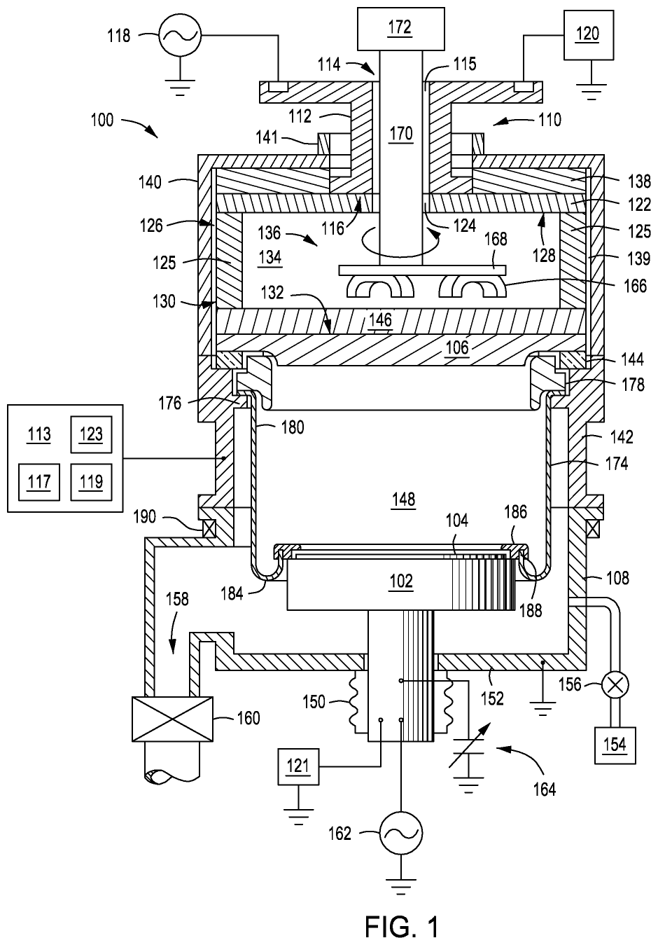

FIG. 1 depicts a schematic, cross-sectional view of a processing chamber 100 (e.g., a physical vapor deposition (PVD)) in accordance with some embodiments of the present disclosure. Examples of suitable PVD chambers include the ALPS® Plus and SIP ENCORE® PVD processing chambers, both commercially available from Applied Materials, Inc., of Santa Clara, Calif. Other processing chambers from Applied Materials, Inc. or other manufacturers may also benefit from the inventive apparatus disclosed herein.

The processing chamber 100 contains a substrate support 102 for receiving a substrate 104 thereon, and a sputtering source, such as a target 106. The substrate support 102 is located within an interior volume at least partially defined by a wall 108 (e.g., a grounded enclosure), which may be a chamber wall (as shown) or a grounded shield.

The processing chamber 100 includes a feed structure 110 for coupling RF and DC energy to the target 106. The feed structure 110 is an apparatus for coupling RF energy and DC energy, to the target 106, or to an assembly containing the target 106, for example, as described herein. In some embodiments, the feed structure 110 may be tubular. The feed structure 110 includes a body 112 having a first end 114 and a second end 116 opposite the first end 114. In some embodiments, the body 112 further includes a central opening 115 disposed through the body 112 from the first end 114 to the second end 116. The feed structure 110 may have a suitable length that facilitates substantially uniform distribution of the respective RF and DC energy about the perimeter of the feed structure 110. For example, in some embodiments, the feed structure 110 may have a length of about 0.75 to about 12 inches, or about 3.26 inches. In some embodiments, where the body 112 does not have a central opening, the feed structure 110 may have a length of about 0.5 to about 12 inches.

The first end 114 of the feed structure 110 can be coupled to an RF power source 118 and to a DC power source 120, which can be respectively utilized to provide RF and DC energy to the target 106. For example, the DC power source 120 may be utilized to apply a negative voltage, or bias, to the target 106. In some embodiments, RF energy supplied by the RF power source 118 may range in frequency from about 2 MHz to about 60 MHz, or, for example, non-limiting frequencies such as 2 MHz, 13.56 MHz, 27.12 MHz, or 60 MHz can be used. In some embodiments, a plurality of RF power sources may be provided (i.e., two or more) to provide RF energy in a plurality of the above frequencies. The feed structure 110 may be fabricated from suitable conductive materials to conduct the RF and DC energy from the RF power source 118 and the DC power source 120. Optionally, the DC power source 120 may be alternatively coupled to the target without going through the feed structure 110.

The second end 116 of the body 112 is coupled to a source distribution plate 122. The source distribution plate 122 includes a hole 124 disposed therethrough and aligned with the central opening 115 of the body 112. The source distribution plate 122 may be fabricated from suitable conductive materials to conduct the RF and DC energy from the feed structure 110. The source distribution plate 122 may be coupled to the target 106 via a conductive member 125. The conductive member 125 may be a tubular member having a first end 126 coupled to a target-facing surface 128 of the source distribution plate 122 proximate the peripheral edge of the source distribution plate 122. The conductive member 125 further includes a second end 130 coupled to a source distribution plate-facing surface 132 of the target 106 (or to the backing plate 146 of the target 106) proximate the peripheral edge of the target 106.

A cavity 134 may be defined by the inner-facing walls of the conductive member 125, the target-facing surface 128 of the source distribution plate 122 and the source distribution plate-facing surface 132 of the target 106. The cavity 134 is fluidly coupled to the central opening 115 of the body 112 via the hole 124 of the source distribution plate 122. The cavity 134 and the central opening 115 of the body 112 may be utilized to at least partially house one or more portions of a rotatable magnetron assembly 136 as illustrated in FIG. 1. In some embodiments, the cavity may be at least partially filled with a cooling fluid, such as water (H₂O) or the like.

A ground shield 140 is shown covering at least some portions of the processing chamber 100 above the target 106 in FIG. 1. In some embodiments, the ground shield 140 could be extended below the target 106 to enclose the substrate support 102 as well. The ground shield 140 may be provided to cover the outside surfaces of a lid of the processing chamber 100. The ground shield 140 may be coupled to ground, for example, via a ground connection of the processing chamber 100 body. The ground shield 140 has a central opening to allow the feed structure 110 to pass through the ground shield 140 to be coupled to the source distribution plate 122. The ground shield 140 may comprise any suitable conductive material, such as aluminum, copper, or the like.

An insulative gap 139 is provided between the ground shield 140 and the outer surfaces of the source distribution plate 122, the conductive member 125, and the target 106 (and/or backing plate 146) to prevent the RF and DC energy from being routed directly to ground. The insulative gap 139 may be filled with air or some other suitable dielectric material, such as a ceramic, a plastic, or the like.

A ground collar 141 may be disposed about body 112 and a lower portion of the feed structure 110. The ground collar 141 is coupled to the ground shield 140 and may be an integral part of the ground shield 140 or a separate part coupled to the ground shield 140 to provide grounding of the feed structure 110. The ground collar 141 may be made from a suitable conductive material, such as aluminum or copper. In some embodiments, a gap disposed between the inner diameter of the ground collar 141 and the outer diameter of the body 112 of the feed structure 110 may be kept to a minimum and be just enough to provide electrical isolation. The gap can be filled with isolating material like plastic or ceramic or can be an air gap. The ground collar 141 prevents cross-talk between RF feed and the body 112, thereby improving plasma, and processing, uniformity.

An isolator plate 138 may be disposed between the source distribution plate 122 and the ground shield 140 to prevent the RF and DC energy from being routed directly to ground. The isolator plate 138 has a central opening to allow the feed structure 110 to pass through the isolator plate 138 and be coupled to the source distribution plate 122. The isolator plate 138 may comprise a suitable dielectric material, such as a ceramic, a plastic, or the like. Alternatively, an air gap may be provided in place of the isolator plate 138. In embodiments where an air gap is provided in place of the isolator plate, the ground shield 140 may be structurally sound enough to support any components resting upon the ground shield 140.

The target 106 may be supported on an adapter 142 (e.g., a grounded conductive aluminum adapter) through a dielectric isolator 144. The target 106 comprises a material to be deposited on the substrate 104 during sputtering, such as metal (or metal oxide) including, but not limited to, aluminum, copper, gold, tantalum, titanium, and the like. For example, in at least some embodiments the target 106 can be made from tantalum. In at least some embodiments, the tantalum can have a purity of about 99.95% to about 99.995%.

The backing plate 146 may be coupled to the source distribution plate-facing surface 132 of the target 106. The backing plate 146 may comprise a conductive material, such as copper-zinc, copper-chrome, or the same material as the target, such that RF and DC power can be coupled to the target 106 via the backing plate 146. Alternatively, the backing plate 146 may be non-conductive and may include conductive elements (not shown) such as electrical feedthroughs or the like for coupling the source distribution plate-facing surface 132 of the target 106 to the second end 130 of the conductive member 125. The backing plate 146 may be included for example, to improve structural stability of the target 106.

A rotatable magnetron assembly 136 may be positioned proximate a back surface (e.g., source distribution plate-facing surface 132) of the target 106. The rotatable magnetron assembly 136 includes a plurality of magnets 166 supported by a base plate 168. The base plate 168 connects to a rotation shaft 170 coincident with the central axis of the processing chamber 100 and the substrate 104. A motor 172 can be coupled to the upper end of the rotation shaft 170 to drive rotation of the rotatable magnetron assembly 136. The plurality of magnets 166 produce a magnetic field within the processing chamber 100, generally parallel and close to the surface of the target 106 to trap electrons and increase the local plasma density, which in turn increases the sputtering rate. The plurality of magnets 166 produce an electromagnetic field around the top of the processing chamber 100, and plurality of magnets 166 are rotated to rotate the electromagnetic field which influences the plasma density of the process to more uniformly sputter the target 106. For example, the rotation shaft 170 may make about 0 to about 150 rotations per minute.

A lift mechanism including a drive housing (not shown) is coupled to the rotation shaft 170 and configured to selectively raise (or lower) the plurality of magnets 166 of the rotatable magnetron assembly 136 with respect to the back of the target 106. One such lift mechanism is disclosed in commonly-owned U.S. Pat. No. 7,674,360, entitled “Mechanism For Varying The Spacing Between Sputter Magnetron And Target.”

In some embodiments, a magnet 190 may be disposed about the processing chamber 100 for selectively providing a magnetic field between the substrate support 102 and the target 106. For example, as shown in FIG. 1, the magnet 190 may be disposed about the outside of the wall 108 in a region just above the substrate support 102 when in processing position. In some embodiments, the magnet 190 may be disposed additionally or alternatively in other locations, such as adjacent the adapter 142. The magnet 190 may be an electromagnet and may be coupled to a power source (not shown) for controlling the magnitude of the magnetic field generated by the electromagnet.

The substrate support 102 has a material-receiving surface facing the principal surface of the target 106 and supports the substrate 104 to be sputter coated in planar position opposite to the principal surface of the target 106. The substrate support 102 may support the substrate 104 in a central region 148 of the processing chamber 100. The central region 148 (e.g., an interior volume of the processing chamber) is defined as the region above the substrate support 102 during processing (for example, between the target 106 and the substrate support 102 when in a processing position).

In some embodiments, the substrate support 102 may be vertically movable through a bellows 150 connected to a bottom chamber wall 152 to allow the substrate 104 to be transferred onto the substrate support 102 through a slit valve (not shown) in the lower portion of processing the processing chamber 100 and thereafter raised to a deposition, or processing position.

One or more processing gases may be supplied from a gas source 154 through a mass flow controller 156 into the lower part of the processing chamber 100. For example, the gas source 154 can be configured to supply a first gas at a first flow rate to the substrate support 102 while simultaneously supplying the first gas at a second flow rate to an interior volume (e.g., the central region 148 of the processing chamber 100, via the mass flow controller 156, to the substrate support 102, as described below. An exhaust port 158 may be provided and coupled to a pump (not shown) via a valve 160 for exhausting the interior of the processing chamber 100 and facilitating maintaining a desired pressure inside the processing chamber 100.

An RF bias power source 162 may be coupled to the substrate support 102 to induce a negative DC bias on the substrate 104. In addition, in some embodiments, a negative DC self-bias may form on the substrate 104 during processing. For example, RF power supplied by the RF bias power source 162 may range in frequency from about 2 MHz to about 60 MHz, for example, non-limiting frequencies such as 2 MHz, 13.56 MHz, or 60 MHz can be used. In other applications, the substrate support 102 may be grounded or left electrically floating. For example, a capacitance tuner 164 may be coupled to the substrate support pedestal for adjusting voltage on the substrate 104 for applications where RF bias power may not be desired.

In some embodiments, the processing chamber 100 may further include a grounded bottom shield 174 connected to a ledge 176 of the adapter 142. A dark space shield 178 may be supported on the bottom shield 174 and may be fastened to the bottom shield 174 by screws or other suitable manner. The metallic threaded connection between the bottom shield 174 and the dark space shield 178 allows the bottom shield 174 and the dark space shield 178 to be grounded to the adapter 142. The adapter 142 in turn is sealed and grounded to the wall 108. Both the bottom shield 174 and the dark space shield 178 are typically formed from hard, non-magnetic stainless steel.

The bottom shield 174 extends downwardly and may include a generally tubular portion 180 having a generally constant diameter. The bottom shield 174 extends along the walls of the adapter 142 and the wall 108 downwardly to below a top surface of the substrate support 102 and returns upwardly until reaching a top surface of the substrate support 102 (e.g., forming a generally u-shaped portion 184 at the bottom).

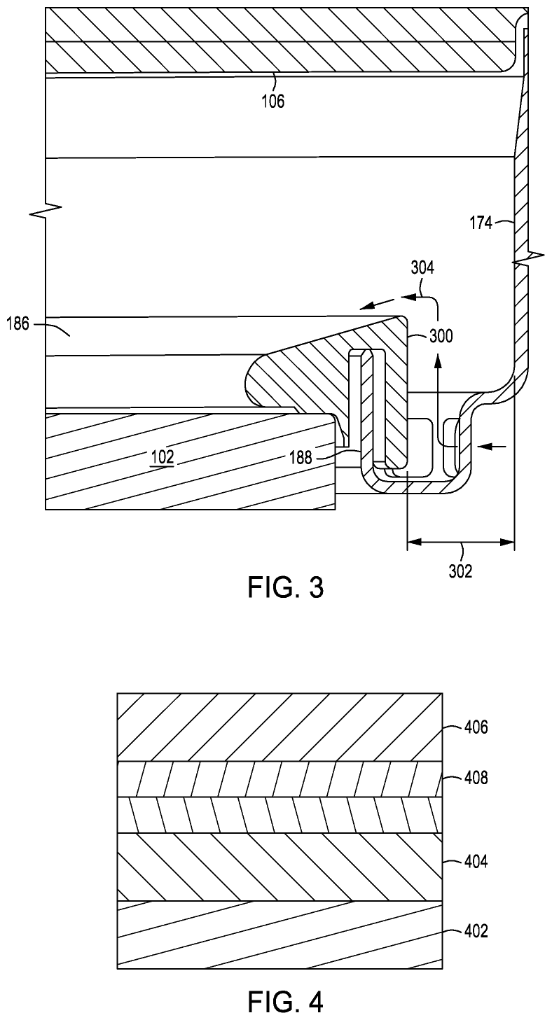

A cover ring 186 rests on the top of the upwardly extending inner portion 188 of the bottom shield 174 when the substrate support 102 is in a lower, loading position but rests on the outer periphery of the substrate support 102 when the substrate support 102 is in an upper, deposition position to protect the substrate support 102 from sputter deposition. Unlike conventional cover rings, which include a protruding edge or ear which can cause unwanted variations/deviations during deposition processes, the cover ring 186 does not include such structure, e.g., the cover ring 186 includes a relatively straight or flat edge 300 along the outer diameter of the cover ring 186. The inventors have found that using a cover ring 186 without a protruding edge or ear reduces, if not eliminates, variations/deviations during deposition processes (e.g., provides process repeatability). For example, a distance 302 between the flat edge 300 of the cover ring 186 and the bottom shield 174 is greater without the protruding edge or ear, which, in turn, provides more space for an inflow of process gas (as shown in FIG. 3 by arrows 304). An additional deposition ring (not shown) may be used to shield the periphery of the substrate 104 from deposition.

The processing chamber 100 includes a system controller 113 to control the operation of the processing chamber 100 during processing. The system controller 113 comprises a central processing unit (CPU) 117, a memory 119 (e.g., non-transitory computer readable storage medium) having instructions stored thereon, and support circuits 123 for the CPU 117 and facilitates control of the components of the processing chamber 100. The system controller 113 may be one of any form of general-purpose computer processor that can be used in an industrial setting for controlling various chambers and sub-processors. The memory 119 stores software (source or object code) that may be executed or invoked to control the operation of the processing chamber 100 in the manner described herein.

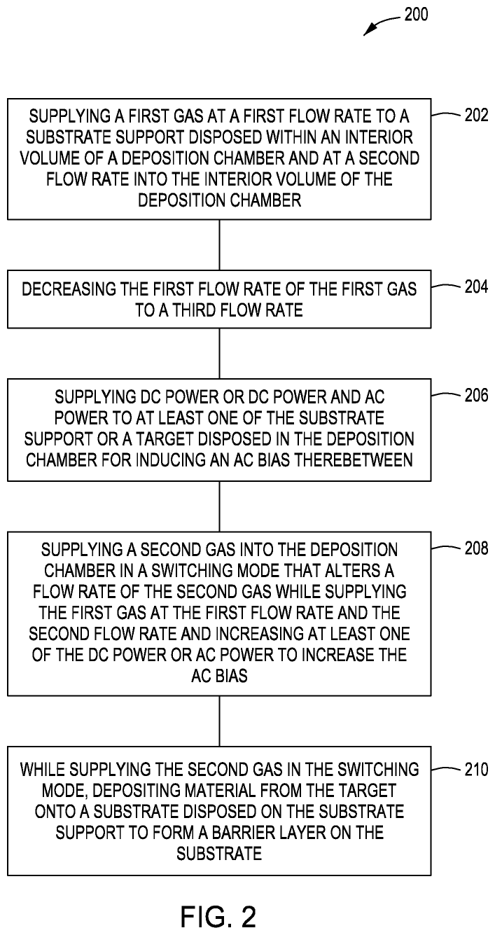

FIG. 2 is a flowchart of a method 200 for processing a substrate in accordance with at least some embodiments of the present disclosure. The method 200 can be performed in a suitable process chamber such as the processing chamber 100 described above, for example, under control of the system controller 113. The method is further described with reference to FIG. 4, which depicts a schematic cross-sectional side view of a substrate formed using the method of FIG. 2 in accordance with at least some embodiments of the present disclosure.

At 202, a first gas can be supplied at a first flow rate to a substrate support disposed within an interior volume of a deposition chamber while simultaneously supplying the first gas at a second flow rate into the interior volume of the deposition chamber. In at least some embodiments, a substrate 400 can have a base layer 402. For example, the base layer can be formed of silicon, silicon oxide, germanium, etc. In at least some embodiments, the base layer can be formed from silicon oxide. Disposed atop the base layer 402 can be one more layers of metal. For example, in at least some embodiments, a metal layer 404 can be disposed atop the base layer 402. In some embodiments the metal layer 404 is a copper layer.

The system controller 113 can control the gas source 154 to supply one or more gases through the mass flow controller 156. For example, the first gas can be an inert gas, such as a noble gas. For example, the first gas can be at least one of argon, helium, krypton, neon, radon, or xenon. In at least some embodiments, the first gas can be argon. The first gas can be supplied to the substrate support (e.g., the substrate support 102) at a first flow rate that is greater than 0 sccm and up to about 20 sccm. In at least some embodiments, the first gas can be applied to a backside of the substrate 400 disposed on the substrate support to facilitate heating the substrate, e.g., to a temperature of about 200° C. to about 300° C., during operation, e.g., during physical vapor deposition for forming a barrier that can be used between layers of metal. The first gas is flowed to the backside of the substrate, which can be electrostatically chucked to the substrate support surface. Providing the first gas to the backside of a substrate provides a stable substrate temperature during a deposition process (e.g., substrate support acts as heat source/heat sink, and the backside first gas functions as heat exchange medium). The backside flow at 202 quickly ramps up the backside pressure. The flow of the first gas can then be decreased to a stable value to hold the backside pressure. Moreover, the first gas can be supplied to the interior volume (e.g., the central region 148) at a second flow rate of about 50 sccm to about 500 sccm, e.g., to facilitate plasma formation in the interior volume.

Next, at 204, the first flow rate of the first gas can be decreased to a third flow rate. For example, the third flow rate can be about 0 to about 19 sccm. For example, after the first gas is provided sufficiently to achieve the desired the backside pressure, the flow of the first gas can then be decreased to a stable value to maintain the backside pressure at a desired value or within a desired range.

Next, at 206, DC power alone or a combination of DC power and AC power can be supplied to at least one of the substrate support or a target disposed in the deposition chamber for inducing a low AC bias therebetween. For example, the system controller 113 can control the DC power source 120 and the RF power source 118 to induce the AC bias between substrate support or a target. For example, the system controller 113 can supply DC power from about 500 watts to about 20,000 watts and supply AC power from about 0 to about 900 watts. In at least some embodiments, the DC power can be about 500 watts and the AC power can be 0 watts, e.g., the AC power is not used, to ignite a plasma.

The inventors have found that supplying a second gas during physical vapor deposition in a switching mode (e.g., switching supply of the second gas) improves barrier formation used between two layers of materials, such as copper, aluminum, silicon, tungsten, or other metal suitable for substrate fabrication. In at least some embodiments, the two layers of metal can be the metal layer 404, which forms a bottom layer of metal, and a metal layer 406 (e.g., an aluminum layer), which forms a top layer of metal, or vice versa. Suitable metals for forming the barrier between the two layers of metal can be tantalum, etc. Accordingly, in embodiments, the target can be made from tantalum and/or titanium.

Next, at 208, a second gas can be supplied into the deposition chamber in the switching mode that alters a flow rate of the second gas while supplying the first gas at the first flow rate and the second flow rate and increasing at least one of the DC power or AC power to increase the AC bias (e.g., a high AC bias). For example, in at least some embodiments, the second gas can be nitrogen.

The switching mode comprises switching between a fourth flow rate and a fifth flow rate, which is much less than the fourth flow rate. For example, the fourth flow rate can be about 10 sccm to about 350 sccm and the fifth flow rate is about 0 to about 200 sccm. In at least some embodiments, the second gas can be supplied at a fourth flow rate of about 90 sccm and a fifth flow rate of about 0 sccm (e.g., little or no flow of the second gas). Additionally, the second gas can be supplied at the fourth flow rate and the fifth flow rate for about 1 millisecond to about 10 seconds. For example, in at least some embodiments, during physical vapor deposition, the switching mode can include supplying the second gas at a flow rate of about 200 sccm for about 1.5 seconds to about 2 seconds, then not supplying the second gas or supplying the second gas at a relatively low flow rate (e.g., at about 0 sccm) for about 0.1 second to about 2 seconds, then supplying the second gas at a flow rate of about of about 50 sccm for about 3 seconds to about 5 seconds, then not supplying the second gas or supplying the second gas at a relatively low flow rate, and so on. At the fifth flow rate little to no nitrogen is deposited on the substrate (e.g., a layer of predominately Ta is formed on the substrate. For example, when a layer of TaN is deposited, the switching mode can include supplying the second gas at a flow rate of about 200 sccm for about 1.5 seconds to about 2 seconds (e.g., gas supply in an on mode), and when a layer of Ta is deposited, not supplying the second gas (or supplying the second gas at about 0 sccm to about 10 sccm) for about 0.1 second to about 2 seconds, such that little to no nitrogen is deposited in the Ta later.

As noted above, as the cover ring 186 does not include the protruding edge or ear, variations/deviations during deposition processes are significantly reduced, if not eliminated. That is, moving the cover ring 186 between the lower position and the upper position sometimes moves the cover ring 186 off center, but because the distance between the cover ring 186 and the bottom shield 174 is relatively large, the second gas can freely flow over the cover ring 186 during deposition, e.g., gas in-flow dynamic is advantageously less sensitive to cover ring centering.

Additionally, at 208, at least one of the DC power or AC power can be increased to increase the AC bias. For example, in at least some embodiments, the DC power can be increased from about 500 watts to about 20000 watts and the AC power can be increased from about 0 watts to about 900 watts, to increase the AC bias.

For example, at 208 the DC power can first be provided (e.g., 500 W) to initially ignite the plasma (e.g., Ar plasma) and deposit a Ta layer first (e.g., no or little nitrogen gas being supplied, for example, at the fifth flow rate), then DC power can be maintained at 500 W with no AC power being supplied and nitrogen can be supplied at about 100 sccm (e.g., at the fourth flow rate). Thereafter, with a stable plasma provided in an interior (e.g., the central region 148) of the process chamber, DC power can ramped up and the AC power can be ramped up/down to increase the AC bias, while nitrogen is supplied between the fourth and fifth flow rate. For example, with a stable plasma provided in the central region 148, in at least some embodiments, when depositing the Ta and the TaN, the DC power can be about 5000 W to about 15,000 W, and, when depositing the Ta, AC power can be ramped up to about 500 W to about 800 W, and, when depositing the TaN, the AC power can be ramped down to about 200 W to about 400 W.

During 208, material from the target can be directed toward a substrate facing surface of the substrate support, e.g., to deposit material on a substrate disposed on the substrate support, as depicted at 210. For example, by supplying the second gas, e.g., nitrogen, using the switching mode, while depositing a material from the target, e.g., tantalum, a barrier layer 408 that includes alternative tantalum/tantalum nitride (Ta/TaN) structure can be formed atop a bottom layer, e.g., the metal layer 404, of a substrate and on which a second layer (e.g., the metal layer 406) can be deposited. For example, during 210, with little or no nitrogen being supplied into the chamber, a layer of Ta can be deposited to form a Ta film. Additionally, at 210, with nitrogen being supplied into the chamber, a layer of TaN can be deposited to form a TaN film, e.g., atop the Ta film. That is, after physical vapor deposition, the substrate will include the metal layer 404 on which the barrier layer 408 (e.g., alternating film layers) that includes alternative Ta/TaN structure (e.g., Ta/TaN films) is deposited on which the top layer of metal layer 406 can subsequently be deposited. In at least some embodiments, the barrier layer 408 can include 6 alternating layers of Ta/TaN structure having an overall thickness of about 60 nm, e.g., each of the Ta and TaN layers can have a thickness of about 10 nm. The inventors have found that the more alternating layers of Ta and TaN, the more structurally sound the barrier layer 408 will be, e.g., having a decreased RC.

While the foregoing is directed to embodiments of the present disclosure, other and further embodiments of the disclosure may be devised without departing from the basic scope thereof.

1. A method for processing a substrate, comprising:
supplying a first gas at a first flow rate to a substrate support disposed within an interior volume of a deposition chamber and at a second flow rate into the interior volume of the deposition chamber;
decreasing the first flow rate of the first gas to a third flow rate;
supplying at least one of a DC power or DC power and an AC power to at least one of the substrate support or a target disposed in the deposition chamber for inducing an AC bias therebetween;
supplying a second gas into the deposition chamber in a switching mode that alters a flow rate of the second gas while supplying the first gas at the second flow rate and the third flow rate and increasing at least one of the DC power or AC power to increase the AC bias; and
while supplying the second gas in the switching mode, depositing material from the target onto a substrate disposed on the substrate support to form a barrier layer on the substrate.

2. The method of claim 1, further comprising heating the substrate to a temperature of about of about 200° C. to about 300° C.

3. The method of claim 1, wherein supplying the first gas comprises supplying at least one of argon, helium, krypton, neon, radon, or xenon.

4. The method of claim 1, wherein supplying the second gas comprises supplying nitrogen.

5. The method of claim 1, wherein the first flow rate is about 0 sccm to about 20 sccm,
wherein the second flow rate is about 50 sccm to about 500 sccm, and
wherein the third flow rate is about 0 to about 20 sccm.

6. The method of claim 1, wherein supplying the second gas into the deposition chamber in the switching mode comprises switching between a fourth flow rate and a fifth flow rate that is different from the fourth flow rate.

7. The method of claim 6, wherein the fourth flow rate is about 10 sccm to about 350 sccm and the fifth flow rate is about 0 to about 200 sccm.

8. The method of claim 7, further comprising supplying the second gas at the fourth flow rate and the fifth flow rate for about 1 millisecond to about 10 seconds.

9. The method of claim 1, wherein supplying the at least one of the DC power and the DC power and AC power for inducing the AC bias comprises supplying DC power from about 500 watts to about 20,000 watts and supplying AC power from about 0 to about 900 watts.

10. The method of claim 1, wherein the target is tantalum (Ta), and wherein depositing material from the target onto the substrate comprises depositing at least one of a Ta film, a tantalum nitride (TaN) film, or depositing alternating layers of Ta and TaN films.

11. The method of claim 10, wherein each of the Ta film and TaN film have a thickness of about 10 nm.

12. The method of claim 10, wherein the Ta can have a purity of about 99.95% to about 99.995%.

13. The method of claim 1, further comprising forming the barrier layer with a thickness of about 60 nm.

14. A non-transitory computer readable storage medium having instructions stored thereon that, when executed by a processor, cause a method for processing a substrate to be performed, the method comprising:
supplying a first gas at a first flow rate to a substrate support disposed within an interior volume of a deposition chamber and at a second flow rate into the interior volume of the deposition chamber;
decreasing the first flow rate of the first gas to a third flow rate;
supplying at least one of a DC power or DC power and an AC power to at least one of the substrate support or a target disposed in the deposition chamber for inducing an AC bias therebetween;
supplying a second gas into the deposition chamber in a switching mode that alters a flow rate of the second gas while supplying the first gas at the second flow rate and the third flow rate and increasing at least one of the DC power or AC power to increase the AC bias; and
while supplying the second gas in the switching mode, depositing material from the target onto a substrate disposed on the substrate support to form a barrier layer on the substrate.

15. The non-transitory computer readable storage medium of claim 14, further comprising heating the substrate to a temperature of about of about 200° C. to about 300° C.

16. The non-transitory computer readable storage medium of claim 14, wherein supplying the first gas comprises supplying at least one of argon, helium, krypton, neon, radon, or xenon.

17. The non-transitory computer readable storage medium of claim 14, wherein supplying the second gas comprises supplying nitrogen.

18. The non-transitory computer readable storage medium of claim 14, wherein the first flow rate is about 0 sccm to about 20 sccm, wherein the second flow rate is about 50 sccm to about 500 sccm, and wherein the third flow rate is about 0 to about 20 sccm.

19. The non-transitory computer readable storage medium of claim 14, wherein supplying the second gas into the deposition chamber in the switching mode comprises switching between a fourth flow rate and a fifth flow rate that is different from the fourth flow rate.

20. A deposition chamber for processing a substrate, comprising:
a gas source configured to provide a plurality of gases into the deposition chamber;
a DC power source and an RF power source configured to induce an AC bias between a substrate support and a target each disposed within an interior volume of the deposition chamber; and
a controller configured to:
supply a first gas from the gas source at a first flow rate to the substrate support disposed within the interior volume of the deposition chamber and at a second flow rate into the interior volume of the deposition chamber;
decrease the first flow rate of the first gas to a third flow rate;
supply at least one of a DC power or DC power and an AC power to at least one of the substrate support or the target disposed in the deposition chamber for inducing the AC bias therebetween;
supply a second gas from the gas source into the deposition chamber in a switching mode that alters a flow rate of the second gas while supplying the first gas at the second flow rate and the third flow rate and increasing at least one of the DC power or AC power to increase the AC bias; and
while supplying the second gas in the switching mode, depositing material from the target onto a substrate disposed on the substrate support to form a barrier layer of the substrate.
